(19) United States
(12) Patent Application Publication
(10) Pub. No.: US 2026/0190281 A1
(43) Pub. Date: Jul. 2, 2026

(54) Information Handling System Immersion Cooled Power Supply Unit

(71) Applicant: Dell Products L.P., Round Rock, TX (US)

(72) Inventors: Owen Kidd, Cedar Park, TX (US); Jonathan Foster Lewis, Round Rock, TX (US)

(21) Appl. No.: 18/976,491

(22) Filed: Dec. 11, 2024

(51) Int. Cl. H05K 7/20

(52) U.S. Cl. CPC H05K 7/20236; H05K 7/20254; H05K 7/20272; H05K 7/20927

(57) ABSTRACT

A power supply unit cooling system for use with an information handling system. The power supply unit cooling system includes a cooling system and an immersion cooled power supply unit thermally coupled with the cooling system, the immersion cooled power supply unit. The immersion cooled power supply unit includes: an internally immersed cooling chamber, the internally immersed chamber holding a thermally conductive liquid solution; an external liquid cooling interface, the external liquid cooling interface including an external cooling liquid chamber, the external cooling liquid chamber holding liquid, the external cooling liquid chamber being supplied with cooled liquid and extracting heated liquid; and, a heat transfer interface, the heat transfer interface being thermally coupled between the internally immersed cooling chamber and the external liquid cooling interface, the heat transfer interface extracting heat from the internally immersed cooling chamber and transferring the extracted heat to the external liquid cooling interface.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing an information handling system with an immersion cooled power supply unit.

In one embodiment, the invention relates to a power supply unit for an information handling system, comprising: an internally immersed cooling chamber, the internally immersed chamber holding a thermally conductive liquid solution; an external liquid cooling interface, the external liquid cooling interface including an external cooling liquid chamber, the external cooling liquid chamber holding liquid, the external cooling liquid chamber being supplied with cooled liquid and extracting heated liquid; and, a heat transfer interface, the heat transfer interface being thermally coupled between the internally immersed cooling chamber and the external liquid cooling interface, the heat transfer interface extracting heat from the internally immersed cooling chamber and transferring the extracted heat to the external liquid cooling interface.

In another embodiment, the invention relates to a power supply unit cooling system for use in an information handling system comprising: a cooling system; and, an immersion cooled power supply unit thermally coupled with the cooling system, the immersion cooled power supply unit comprising: an internally immersed cooling chamber, the internally immersed chamber holding a thermally conductive liquid solution; an external liquid cooling interface, the external liquid cooling interface including an external cooling liquid chamber, the external cooling liquid chamber holding liquid, the external cooling liquid chamber being supplied with cooled liquid and extracting heated liquid; and, a heat transfer interface, the heat transfer interface being thermally coupled between the internally immersed cooling chamber and the external liquid cooling interface, the heat transfer interface extracting heat from the internally immersed cooling chamber and transferring the extracted heat to the external liquid cooling interface.

In another embodiment, the invention relates to an information handling system comprising: a chassis; a heat producing component contained within the chassis; and, an immersion cooled power supply unit mounted within the chassis, the immersion cooled power supply unit comprising: an internally immersed cooling chamber, the internally immersed chamber holding a thermally conductive liquid solution; an external liquid cooling interface, the external liquid cooling interface including an external cooling liquid chamber, the external cooling liquid chamber holding liquid, the external cooling liquid chamber being supplied with cooled liquid and extracting heated liquid; and, a heat transfer interface, the heat transfer interface being thermally coupled between the internally immersed cooling chamber and the external liquid cooling interface, the heat transfer interface extracting heat from the internally immersed cooling chamber and transferring the extracted heat to the external liquid cooling interface.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a cut away cross-sectional view of an internally immersed power supply unit.

FIG. 5 shows a rear view of an internally immersed power supply unit.

### DETAILED DESCRIPTION

Various aspects of the present disclosure include an appreciation that various components within information handling systems generate heat. Various aspects of the present disclosure include an appreciation that one example of a heat generating component is a power supply unit for providing power to the information handling system.

Various aspects of the present disclosure include an appreciation that certain information handling systems, such as high-powered server systems, often require additional power input capacity to service demanding workloads. Various aspects of the present disclosure include an appreciation that known power supply designs are often constrained to about a 3200 W power output capacity in a typical 1RU type power supply unit. Various aspects of the present disclosure include an appreciation that this power constraint can be attributable to limitations associated with the power input line cord. Various aspects of the present disclosure include an appreciation that increasing the power supply output level would likely necessitate either a larger power input cord or a higher count of power input cords. Various aspects of the present disclosure include an appreciation that either of these options are challenging without growing the power supply unit form factors, possibly to be double the size of known power supply designs.

Various aspects of the present disclosure include an appreciation that a wider, longer, or combination thereof, would be desirable to provide a power supply with additional power supply output capacity. Various aspects of the present disclosure include an appreciation that such a higher output capacity power supply unit would likely generate more heat than known power supply units. Various aspects of the present disclosure include an appreciation that the fan units of many known power supply units (e.g., 40 mm fan units) would likely be insufficient to cool this additional heat generated by the higher output capacity power supply unit. Various aspects of the present disclosure include an appreciation that a need for additional power line inputs would also present a constraint on the size available at the rear of the power supply unit for a fan unit.

Various aspects of the present disclosure include an appreciation that known liquid cooled power supply units often require additional piping and heat exchangers, resulting in limiting the overall capacity of the power supply unit.

Various aspects of the present disclosure include an appreciation that it would be desirable to provide an internally immersed power supply unit which could resolve the piping and heat exchange issue without hampering supply capacity. Various aspects of the present disclosure include an appreciation that challenges associated with an internally immersed power supply unit include a need to isolate the external cooling liquid, which can be electrically conductive, from the internal electrical components of the power supply unit. Various aspects of the present disclosure include an appreciation that challenges associated with an internally immersed power supply unit include a need to provide an impedance controlled environment which would be compatible with many high voltage power supply designs. Accordingly, various aspects of the present disclosure include an appreciation that it would be desirable to provide a cooling system which resolves the aforementioned issues.

A system and method are disclosed for providing an information handling system with power supply unit cooling system. In certain embodiments, the power supply unit cooling system cools power supply units for use with high power information handling systems. In certain embodiments, the power supply unit cooling system includes an immersion cooled power supply unit. In certain embodiments, the immersion cooled power supply unit includes an internally immersed cooling chamber, a heat transfer interface, an external liquid cooling interface, or a combination thereof.

In certain embodiments, the internally immersed cooling chamber includes one or more power supply unit power conversion components. In certain embodiments, the internally immersed cooling chamber is flooded with a liquid solution. In certain embodiments, the liquid solution is thermally conductive, has a high electrical impedance, or a combination thereof. In certain embodiments, the internally immersed cooling chamber is sealed against fluid loss. In certain embodiments, the internally immersed cooling chamber provides an egress for printed circuit board components. In certain embodiments, the printed circuit board components include a power supply unit connector. In certain embodiments, the power supply connector includes a printed circuit board connector. In certain embodiments, the printed circuit board connector includes connector edges. In certain embodiments, the connector edges include gold finger connector edges. In certain embodiments, the internally immersed cooling chamber further includes ingress paths for external voltage sources. In certain embodiments, the ingress paths are via the heat transfer interface.

In certain embodiments, the internally immersed cooling chamber includes heat collection components. In certain embodiments, the heat collection components provide a conduit for heat extraction from hotter areas of the power supply unit. In certain embodiments, the heat collection components are thermally coupled to the heat transfer interface. In certain embodiments, the heat collection components include a plurality of heat collection devices which extend across the internally immersed cooling chamber. In certain embodiments, the plurality of heat collection devices extend different lengths depending on the height of any high temperature power supply components contained within the internally immersed cooling chamber.

In certain embodiments, the heat transfer interface provides a mechanism for extracting heat efficiently from the internally immersed cooling chamber. In certain embodiments, the heat transfer interface extracts heat from the internally immersed cooling chamber without any pumping components. In certain embodiments, the heat transfer interface uses direct thermal contact to transfer heat from the internally immersed cooling chamber to the external liquid cooling interface.

In certain embodiments, the external liquid cooling interface includes an external cooling liquid chamber which provides an interfacing facility for interfacing cooling liquid with the heat transfer interface. In certain embodiments, the external cooling liquid chamber provides a liquid block which is thermally coupled with the heat transfer interface. In certain embodiments, the external liquid cooling interface further includes a set of liquid connections. In certain embodiments, the set of liquid connections are exposed external to the power supply unit via a rear wall component of the power supply unit. In certain embodiments, the external liquid cooling interface of the power supply unit uses the set of liquid connections to supply the power supply unit with cooled liquid and to extract heated liquid from the power supply unit. In certain embodiments, an interior surface of the rear wall component provides one of the walls of the chamber. In certain embodiments, the rear wall component includes the set of liquid connections, one or more power line connections, or a combination thereof.

Such a power supply unit cooling system advantageously provides a cooling system for cooling power supply units for use with high power information handling systems such as high power server type information handling systems.

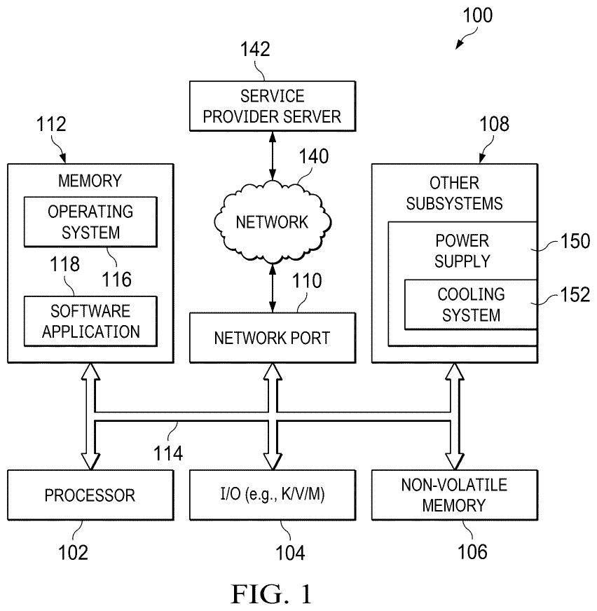

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a power supply unit 150 and a liquid cooling system 152. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the power supply unit 150 and the cooling system 152 provide a power supply unit cooling system. In certain embodiments, the power supply unit cooling system cools power supply units for use with high power information handling systems. In certain embodiments, the power supply unit 150 includes an immersion cooled power supply unit. In certain embodiments, the immersion cooled power supply unit includes an internally immersed cooling chamber, a heat transfer interface, an external liquid cooling interface, or a combination thereof. In certain embodiments, the cooling system 152 is located external to the information handling system 100. In certain embodiments, the cooling system 152 is located within a data center which contains the information handling system. In certain embodiments, the cooling system 152 provides cooled liquid to the power supply unit 150 and receives heated liquid from the power supply unit 150.

In certain embodiments, the internally immersed cooling chamber includes one or more power supply unit power conversion components. In certain embodiments, the internally immersed cooling chamber is flooded with a liquid solution. In certain embodiments, the liquid solution is thermally conductive, has a high electrical impedance, or a combination thereof. In certain embodiments, the internally immersed cooling chamber is sealed against fluid loss. In certain embodiments, the internally immersed cooling chamber provides an egress for printed circuit board components. In certain embodiments, the printed circuit board components include a power supply unit output connector. In certain embodiments, the power supply output connector includes a printed circuit board connector. In certain embodiments, the printed circuit board connector includes connector edges. In certain embodiments, the connector edges include gold finger connector edges. In certain embodiments, the internally immersed cooling chamber further includes ingress paths for external voltage sources. In certain embodiments, the ingress paths are via the heat transfer interface.

In certain embodiments, the internally immersed cooling chamber includes heat collection components. In certain embodiments, the heat collection components provide a conduit for heat extraction from hotter areas of the power supply unit. In certain embodiments, the heat collection components are thermally coupled to the heat transfer interface. In certain embodiments, the heat collection components include a plurality of heat collection devices which extend across the internally immersed cooling chamber. In certain embodiments, the plurality of heat collection devices extend different lengths depending on the height of any high temperature power supply components contained within the internally immersed cooling chamber.

In certain embodiments, the heat transfer interface provides a mechanism for extracting heat efficiently from the internally immersed cooling chamber. In certain embodiments, the heat transfer interface extracts heat from the internally immersed cooling chamber without any pumping components. In certain embodiments, the heat transfer interface uses direct thermal contact to transfer heat from the internally immersed cooling chamber to the external liquid cooling interface.

In certain embodiments, the external liquid cooling interface includes an external cooling liquid chamber which provides an interfacing facility for interfacing cooling liquid with the heat transfer interface. In certain embodiments, the external cooling liquid chamber provides a liquid block which is thermally coupled with the heat transfer interface. In certain embodiments, the external liquid cooling interface further includes a set of liquid connections. In certain embodiments, the set of liquid connections are exposed externally to the power supply unit via a rear wall component of the power supply unit. In certain embodiments, the external liquid cooling interface of the power supply unit uses the set of liquid connections to supply the power supply unit with cooled liquid and to extract heated liquid from the power supply unit. In certain embodiments, an interior surface of the rear wall component provides one of the walls of the external cooling liquid chamber. In certain embodiments, the rear wall component includes the set of liquid connections, one or more power line connections, or a combination thereof.

Such a power supply unit cooling system advantageously provides a cooling system for cooling power supply units for use with high power information handling systems such as high power server type information handling systems.

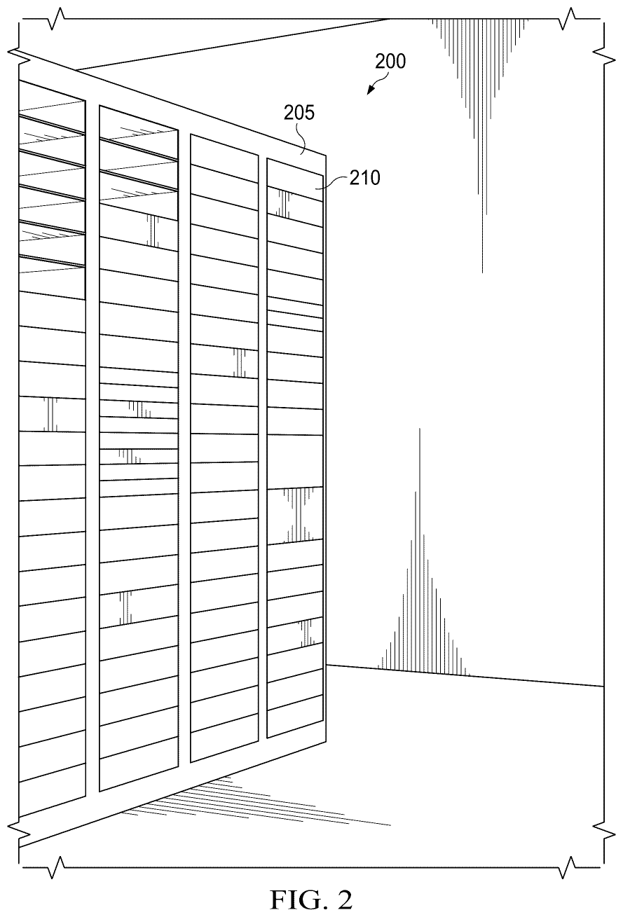

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high.

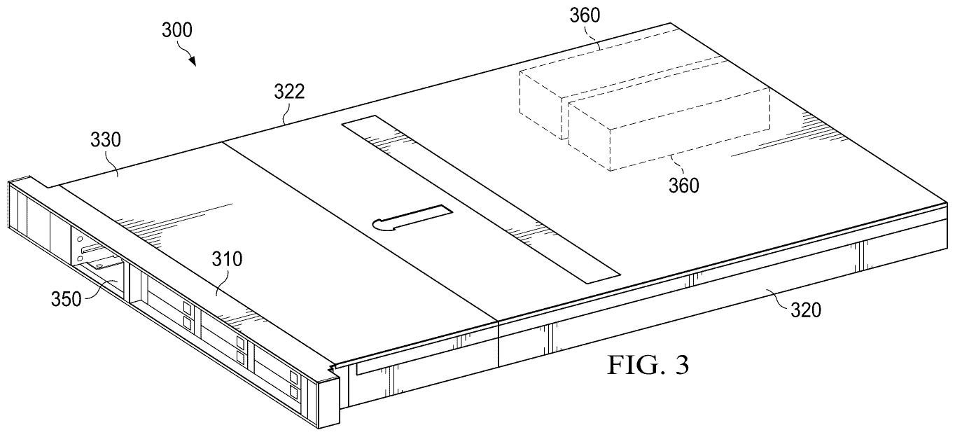

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300.

In certain embodiments, the blade type information handing system 300 includes a one or more device bays 350. In certain embodiments, the information handling system 300 includes one or more power supply units 360. In certain embodiments, one or more power supply units 360 include an immersion cooled power supply unit. In certain embodiments, the immersion cooled power supply unit includes an internally immersed cooling chamber, a heat transfer interface, an external liquid cooling interface, or a combination thereof.

In certain embodiments, the internally immersed cooling chamber includes one or more power supply unit power conversion components. In certain embodiments, the internally immersed cooling chamber is flooded with a liquid solution. In certain embodiments, the liquid solution is thermally conductive, has a high electrical impedance, or a combination thereof. In certain embodiments, the internally immersed cooling chamber is sealed against fluid loss. In certain embodiments, the internally immersed cooling chamber provides an egress for printed circuit board components. In certain embodiments, the printed circuit board components include a power supply unit connector. In certain embodiments, the power supply connector includes a printed circuit board connector. In certain embodiments, the printed circuit board connector includes connector edges. In certain embodiments, the connector edges include gold edge connector edges. In certain embodiments, the internally immersed cooling chamber further includes ingress paths for external voltage sources. In certain embodiments, the ingress paths are via the heat transfer interface.

In certain embodiments, the internally immersed cooling chamber includes heat collection components. In certain embodiments, the heat collection components provide a conduit for heat extraction from hotter areas of the power supply unit. In certain embodiments, the heat collection components are thermally coupled to the heat transfer interface. In certain embodiments, the heat collection components include a plurality of heat collection devices which extend across the internally immersed cooling chamber. In certain embodiments, the plurality of heat collection devices extend different lengths depending on the height of any high temperature power supply components contained within the internally immersed cooling chamber.

In certain embodiments, the heat transfer interface provides a mechanism for extracting heat efficiently from the internally immersed cooling chamber. In certain embodiments, the heat transfer interface extracts heat from the internally immersed cooling chamber without any pumping components. In certain embodiments, the heat transfer interface uses direct thermal contact to transfer heat from the internally immersed cooling chamber to the external liquid cooling interface.

In certain embodiments, the external liquid cooling interface includes an external cooling liquid chamber which provides an interfacing facility for interfacing cooling liquid with the heat transfer interface. In certain embodiments, the external cooling liquid chamber provides a liquid block which is thermally coupled with the heat transfer interface. In certain embodiments, the external liquid cooling interface further includes a set of liquid connections. In certain embodiments, the set of liquid connections are exposed externally to the power supply unit via a rear wall component of the power supply unit. In certain embodiments, the external liquid cooling interface of the power supply unit uses the set of liquid connections to supply the power supply unit with cooled liquid and to extract heated liquid from the power supply unit. In certain embodiments, an interior surface of the rear wall component provides one of the walls of the external cooling liquid chamber. In certain embodiments, the rear wall component includes the set of liquid connections, one or more power line connections, or a combination thereof.

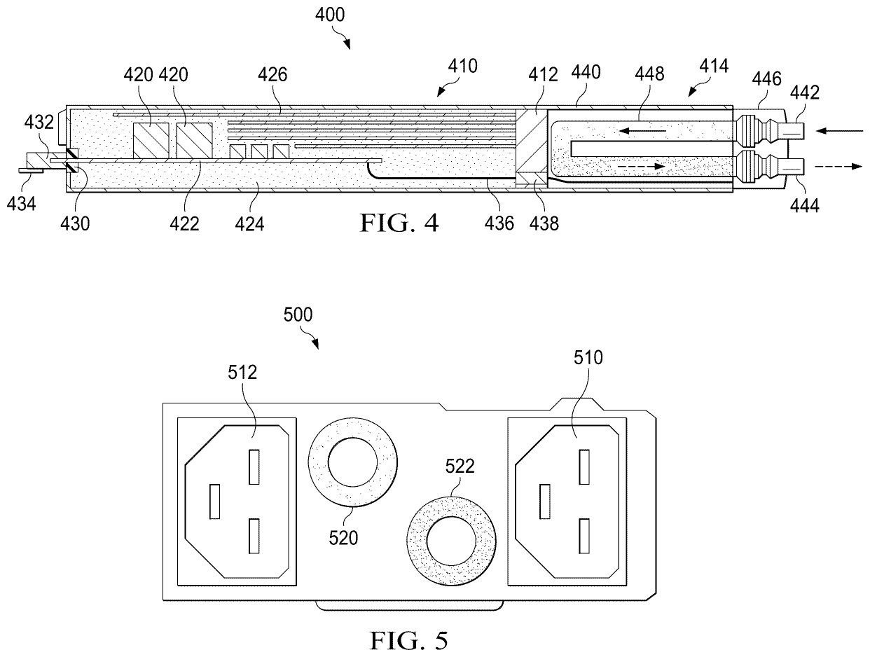

FIG. 4 shows a cut away cross-sectional view of an immersion cooled power supply unit 400. In certain embodiments, the immersion cooled power supply unit 400 corresponds to power supply unit 150 and power supply unit, 360. In certain embodiments, the immersion cooled power supply unit 400 includes an internally immersed cooling chamber 410, a heat transfer interface 412, an external liquid cooling interface 414, or a combination thereof.

In certain embodiments, the internally immersed cooling chamber 410 includes one or more power supply unit power conversion components 420 mounted on a power supply unit printed circuit board 422. In certain embodiments, the internally immersed cooling chamber is flooded with a liquid solution 424. In certain embodiments, the liquid solution 424 is thermally conductive, has a high electrical impedance, or a combination thereof.

In certain embodiments, the internally immersed cooling chamber 410 includes heat collection components 426. In certain embodiments, the heat collection components 426 provide conduits for heat extraction from hotter areas of the power supply unit 400. In certain embodiments, the heat collection components 426 are thermally coupled to the heat transfer interface 412. In certain embodiments, the heat collection components 426 include a plurality of heat collection devices which laterally extend across the interior of immersed cooling chamber 410. In certain embodiments, the plurality of heat collection devices 426 extend different lengths depending on the height of any high temperature power supply components contained within the internally immersed cooling chamber.

In certain embodiments, the internally immersed cooling chamber is sealed against fluid loss via a chamber seal 430. In certain embodiments, the internally immersed cooling chamber provides an egress for the power supply unit printed circuit board 422. In certain embodiments, the printed circuit board 422 includes a power supply unit connector 432. In certain embodiments, the power supply connector 432 includes a printed circuit board connector. In certain embodiments, the printed circuit board connector includes connector edges 434. In certain embodiments, the connector edges 434 include gold edge connector edges. In certain embodiments, the internally immersed cooling chamber 410 further includes a signal path 436, which can include one or more electrical wires, for coupling external voltage sources to the power supply unit printed circuit board 422. In certain embodiments, the ingress paths are via the heat transfer interface 412.

In certain embodiments, the heat transfer interface 412 provides a mechanism for extracting heat efficiently from the internally immersed cooling chamber 410. In certain embodiments, the heat transfer interface 412 extracts heat from the internally immersed cooling chamber without any pumping components. In certain embodiments, the heat transfer interface 412 uses direct thermal contact to transfer heat from the internally immersed cooling chamber to the external liquid cooling interface. In certain embodiments, the heat transfer interface 412 includes a path 438 via which the signal path 436 passes. In certain embodiments, the path 438 is sealed around the signal path 436 to prevent intermingling of the liquid contained within the immersed cooling chamber 410 and liquid contained within the external liquid cooling interface 414.

In certain embodiments, the external liquid cooling interface 414 includes chamber 440 In certain embodiments, the chamber 440 provides a liquid flow 448 which is thermally coupled with the heat transfer interface 412. In certain embodiments, the liquid flow 448 provides a means for providing cooling liquid which interfaces with the heat transfer interface 412 and extracting heated liquid away from the heat transfer interface 412.

In certain embodiments, the external liquid cooling interface 414 further includes a set of liquid connections 442, 444. In certain embodiments, the set of liquid connections 442, 444 are exposed externally to the power supply unit 400 via a rear wall component 446 of the power supply unit 400. In certain embodiments, the set of liquid connections 442, 444 are coupled with a liquid cooling system (such as liquid cooling system 152). In certain embodiments, the external liquid cooling interface 414 of the power supply unit 400 uses the set of liquid connections to supply the power supply unit 400 with cooled liquid from the liquid cooling system and to extract heated liquid from the power supply unit and to return the heated liquid to the liquid cooling system. In certain embodiments, an interior surface of the rear wall component 446 provides one of the walls of the chamber. In certain embodiments, the rear wall component 446 includes the set of liquid connections 442, 444, one or more power line connections 510, 512, or a combination thereof.

FIG. 5 shows a rear view of a rear wall component 500 of a power supply unit. In certain embodiments, the rear wall component 500 corresponds to rear wall component 446. In certain embodiments, the rear wall component 500 includes a set of power line connections 510, 512, a set of liquid connections 520, 522, or a combination thereof. In certain embodiments, the rear wall component has a predefined width and height. In certain embodiments, the predefined width and height correspond to one or more predefined power supply form factors.

In certain embodiments, an external liquid cooling interface of the power supply unit uses the set of liquid connections 520, 522 to supply the power supply unit with cooled liquid (e.g., via liquid connection 520) and to extract heated liquid from the power supply unit (e.g., via liquid connection 522). In certain embodiments, an interior surface of the rear wall component 500 provides a wall of the chamber of the external liquid cooling interface.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A power supply unit for an information handling system, comprising:
an internally immersed cooling chamber, the internally immersed chamber holding a thermally conductive liquid solution;
an external liquid cooling interface, the external liquid cooling interface including an external cooling liquid chamber, the external cooling liquid chamber holding liquid, the external cooling liquid chamber being supplied with cooled liquid and extracting heated liquid; and,
a heat transfer interface, the heat transfer interface being thermally coupled between the internally immersed cooling chamber and the external liquid cooling interface, the heat transfer interface extracting heat from the internally immersed cooling chamber and transferring the extracted heat to the external liquid cooling interface.

2. The power supply unit of claim 1, wherein:
the internally immersed cooling chamber includes a heat collection component, the heat collection component being thermally coupled with the heat transfer interface.

3. The power supply unit of claim 1, wherein:
the internally immersed cooling chamber includes a seal, the seal providing an egress for a power supply connector.

4. The power supply unit of claim 1, wherein:
the heat transfer interface uses direct thermal contact to transfer heat from the internally immersed cooling chamber to the external liquid cooling interface.

5. The power supply unit of claim 1, wherein:
the external liquid cooling interface includes a set of liquid connections, the set of liquid connections supplying the cooled liquid to the external liquid cooling interface and extracting the heated liquid from the external liquid cooling interface.

6. The power supply unit of claim 5, wherein:
the set of liquid connections are exposed externally to the power supply unit via a rear wall component of the power supply unit.

7. A power supply unit cooling system for use in an information handling system comprising:
a cooling system; and,
an immersion cooled power supply unit thermally coupled with the cooling system, the immersion cooled power supply unit comprising:
an internally immersed cooling chamber, the internally immersed chamber holding a thermally conductive liquid solution;
an external liquid cooling interface, the external liquid cooling interface including an external cooling liquid chamber, the external cooling liquid chamber holding liquid, the external cooling liquid chamber being supplied with cooled liquid and extracting heated liquid; and,
a heat transfer interface, the heat transfer interface being thermally coupled between the internally immersed cooling chamber and the external liquid cooling interface, the heat transfer interface extracting heat from the internally immersed cooling chamber and transferring the extracted heat to the external liquid cooling interface.

8. The power supply unit cooling system of claim 7, wherein:
the internally immersed cooling chamber includes a heat collection component, the heat collection component being thermally coupled with the heat transfer interface.

9. The power supply unit cooling system of claim 7, wherein:
the internally immersed cooling chamber includes a seal, the seal providing an egress for a power supply connector.

10. The power supply unit cooling system of claim 1, wherein:
the heat transfer interface uses direct thermal contact to transfer heat from the internally immersed cooling chamber to the external liquid cooling interface.

11. The power supply unit cooling system of claim 7, wherein:
the external liquid cooling interface includes a set of liquid connections, the set of liquid connections supplying the cooled liquid to the external liquid cooling interface and extracting the heated liquid from the external liquid cooling interface.

12. The power supply unit cooling system of claim 11, wherein:
the set of liquid connections are exposed externally to the power supply unit via a rear wall component of the power supply unit.

13. An information handling system comprising:
a chassis;
an immersion cooled power supply unit mounted within the chassis, the immersion cooled power supply unit comprising:
an internally immersed cooling chamber, the internally immersed chamber holding a thermally conductive liquid solution;
an external liquid cooling interface, the external liquid cooling interface including an external cooling liquid chamber, the external cooling liquid chamber holding liquid, the external cooling liquid chamber being supplied with cooled liquid and extracting heated liquid; and,
a heat transfer interface, the heat transfer interface being thermally coupled between the internally immersed cooling chamber and the external liquid cooling interface, the heat transfer interface extracting heat from the internally immersed cooling chamber and transferring the extracted heat to the external liquid cooling interface.

14. The information handling system of claim 13, wherein:
the internally immersed cooling chamber includes a heat collection component, the heat collection component being thermally coupled with the heat transfer interface.

15. The information handling system of claim 13, wherein:
the internally immersed cooling chamber includes a seal, the seal providing an egress for a power supply connector.

16. The information handling system of claim 13, wherein:
the heat transfer interface uses direct thermal contact to transfer heat from the internally immersed cooling chamber to the external liquid cooling interface.

17. The information handling system of claim 13, wherein:
the external liquid cooling interface includes a set of liquid connections, the set of liquid connections supplying the cooled liquid to the external liquid cooling interface and extracting the heated liquid from the external liquid cooling interface.

18. The information handling system of claim 17, wherein:
the set of liquid connections are exposed externally to the power supply unit via a rear wall component of the power supply unit.
